(19) United States
(12) Patent Application Publication
(10) Pub. No.: US 2008/0242097 A1
(43) Pub. Date: Oct. 2, 2008

(54) Selective deposition method

(76) Inventors: Tim Boescke, Dresden (DE); Annette Saenger, Dresden (DE); Stefan Jakschik, Dresden (DE); Christian Fachmann, Dresden (DE); Matthias Patz, Dresden (DE); Alejandro Avellan, Dresden (DE); Thomas Hecht, Dresden (DE); Jonas Sundqvist, Dresden (DE)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 11/729,360

(22) Filed: Mar. 28, 2007

(51) Int. Cl. H01L 21/31; H01L 29/06

(52) U.S. Cl. 438/703; 257/622; 257/E29.005; 257/E21.24

(57) ABSTRACT

The invention refers to a selective deposition method. A substrate comprising at least one structured surface is provided. The structured surface comprises a first area and a second area. The first area is selectively passivated regarding reactants of a first deposition technique and the second area is activated regarding the reactants the first deposition technique. A passivation layer on the second area is deposited via the first deposition technique. The passivation layer is inert regarding a precursors selected from a group of oxidizing reactants. A layer is deposited in the second area using a second atomic layer deposition technique as second deposition technique using the precursors selected form the group of oxidizing reactants.

### BACKGROUND OF THE INVENTION

1. Field of the Invention

The present invention relates to a selective deposition method. Further, the present invention relates to a structured semiconductor device manufactured employing the selective deposition, in particular for an integrated electric circuit.

2. Description of the Related Art

Although in principle applicable to any structured semiconductor device, the following invention and the underlying problem will be explained with respect to the formation of trench capacitors.

Trench capacitors are formed in trenches having a high aspect ratio, i.e. the ratio of the depth of the trench with regard to the diameter of the trench, of more than 20:1 in order to achieve a requested capacitance. A thin uniform layer of dielectric material has to be deposited in the trench. Such a thin layer can be deposited by an atomic layer deposition technique. The quality of the thin layer depends on the transport of reactant gases to the side walls in the trench and of by-products out of trench. The deposition of the thin layer in the collar area of the trench diminishes the diameter of the opening of the trench, which decreases the flow rate of reactants into and out of the trench.

### BRIEF SUMMARY OF THE INVENTION

According to a first aspect of the invention, a selective deposition method comprises the following steps of:
(a) providing a substrate comprising at least one structured surface, the structured surface comprising a first area and a second area;
(b) selectively passivating the first area regarding reactants of a first deposition technique and activating the second area regarding the reactants of the first deposition technique;
(c) depositing a passivation layer on the second area via the first deposition technique, the passivation layer being inert regarding a precursor selected from a group of oxidizing reactants;
(d) depositing a layer in the second area using an atomic layer deposition technique as second deposition technique using the precursor selected form the group of oxidizing reactants.

According to an embodiment of the first aspect of the invention the first deposition technique can be a first atomic layer deposition technique, the reactants being precursors of the first atomic layer deposition technique.

According to an embodiment of the first aspect of the invention the first deposition technique can be one of a gas phase deposition technique, a spin-on technique, a watery solution of the reactant providing the reactant.

According to an embodiment of the first aspect of the invention the selective passivating of the first area and the selective activating of the second area comprises the steps of:
(a) selectively forming a layer of at least one of a silicon oxide layer and a silicon nitride layer on the second area;
(b) selecting an etchant of a group of etchants etching silicon oxide when the layer is formed to comprise silicon oxide and is chosen of a group of etchants etching silicon nitride when the layer is formed to comprise silicon nitride;
(c) applying the etchant to the first area and to the second area for a duration such that parasitic silicon oxide and parasitic silicon nitride are removed in the first area and the formed silicon oxide and the formed silicon nitride remains in the second area.

The purpose of the etchant can be two fold. The etchant removes the parasitic silicon oxide or silicon nitride on which hydroxyl groups and amine groups are usually bound. The etchant transforms the hydroxyl groups and amine groups starting from the silicon oxide and the silicon nitride. Watery solutions generally will form hydroxyl groups on the remains of silicon oxide and silicon nitride. Thus, the silicon nitride and silicon oxide is provided with hydroxyl groups or amine groups in the second area. The hydroxyl and amine groups are activating the surface for atomic layer deposition methods.

According to a second aspect of the invention a selective deposition method comprises the following steps of:
(a) providing a silicon substrate comprising a bottom surface and at least one structured surface, the structured surface comprising a first area and a second area, the first area being closer to the bottom surface than the second area;
(b) selectively depositing at least one of silicon oxide and aluminium oxide on the second area;
(c) etching the first area and the second area using until parasitic silicon hydroxyl is removed in the first area;
(d) depositing a passivation layer on the second area being inert against at least one of water and ozone via a first atomic layer deposition technique, the first atomic layer deposition technique using at least one of hexamethyldisilizane (HN[Si(CH₃)₃]₂), decyltrichlorsilane (SiCl₃C₁₀H₂₁), and octadecyltrichlorsilane (SiCl₃C₁₈H₃₇) as precursor;
(e) activating the passivated first area using at least one of water and ozone for forming silicon hydroxyl in the second area;
(f) depositing a transition metal oxide via a second atomic layer deposition technique using a first precursor selected from water and ozone and a second precursor chosen as compound of one of the constitutional formulas M (R¹CP)₂ (R²)₂ and M R³, R⁴, R⁵, R⁶, wherein M is one of hafnium and zirconium, Cp is cyclopentadienyl, R¹ is independently selected of hydrogen, methyl, ethyl and alkyl, R² is independently selected of hydrogen, methyl, ethyl, alkyl, alkoxy, and halogen; and R³, R⁴, R⁵, and R⁶ are independently selected of alkyl amines.

According to a third aspect of the invention a structured semiconductor device, comprises:

a structured semiconductor substrate in which a trench is formed, the trench comprising a collar region, and a bottle region;
a dielectric layer of at least one of a transition metal oxide and a transition metal nitride formed on the second surface deposited via an atomic layer deposition technique, the bottle region being substantially free of the at least one of the transition metal oxide and the transition metal nitride.

According to a fourth aspect of the invention a memory device comprises the structured semiconductor device according to the third aspect.

### DESCRIPTION OF THE DRAWINGS

### In the Figures:

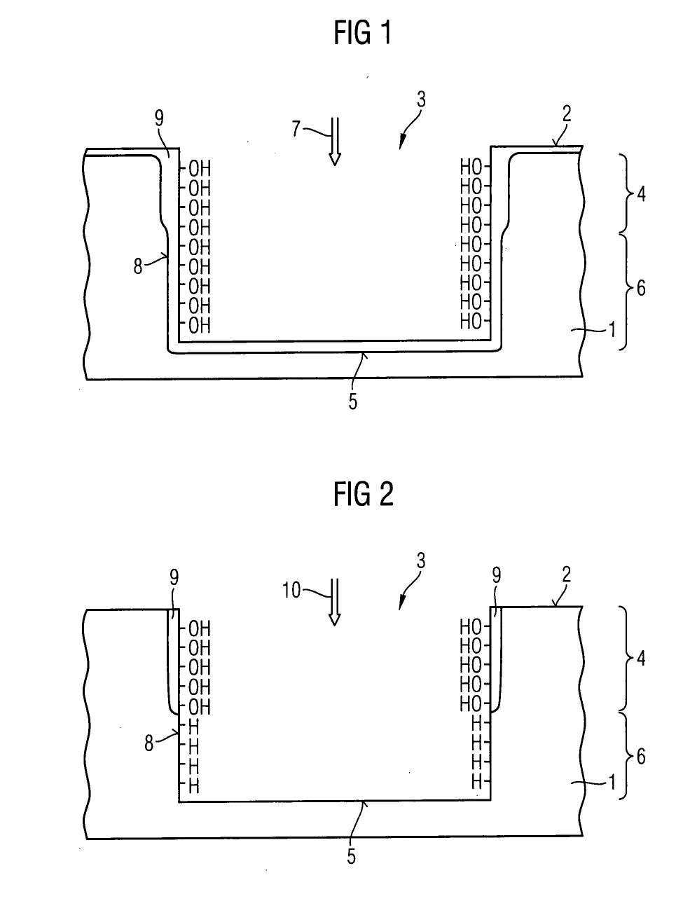

FIGS. 1 to 6 show steps of a first embodiment of a selective deposition method;

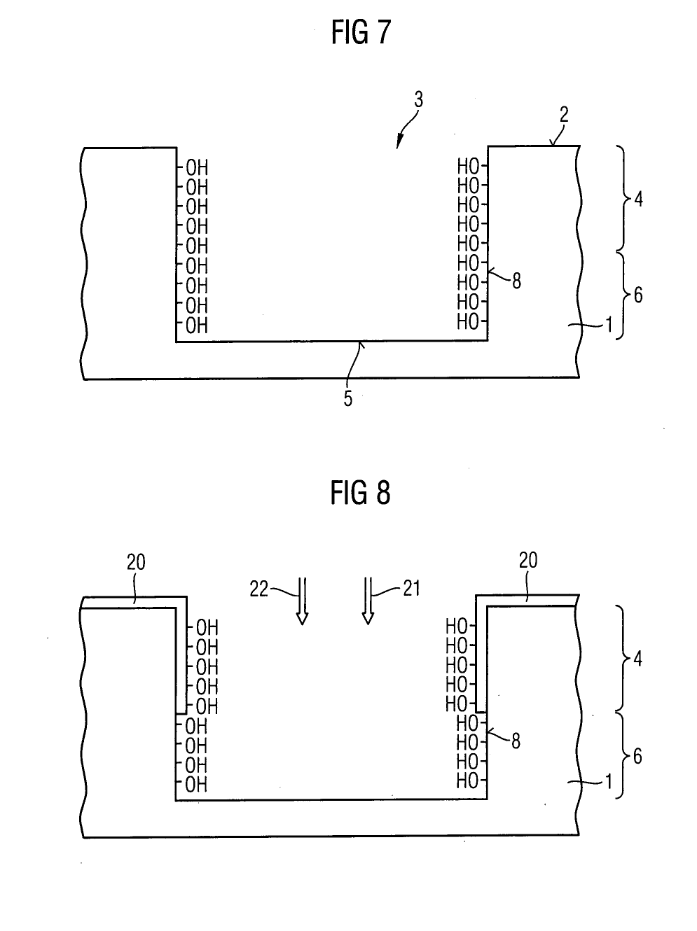

FIGS. 7 to 9 show steps of a second embodiment of a selective deposition method;

FIGS. 10 to 12 show steps of a third embodiment of a selective deposition method; and

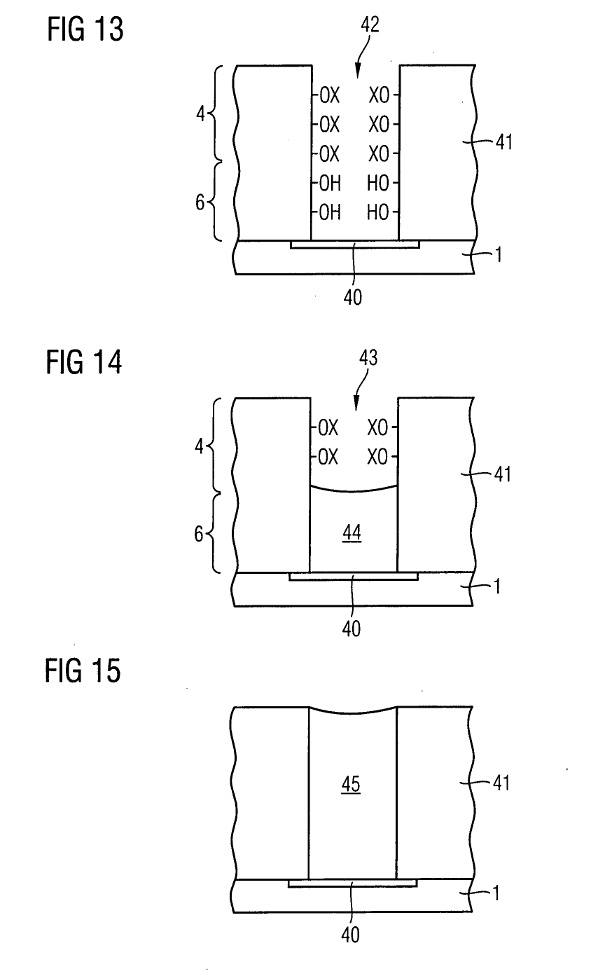

FIGS. 13 to 15 show steps of a forth embodiment.

### DETAILED DESCRIPTION OF THE INVENTION

In the Figures, like numerals refer to the same or similar functionality throughout the several views. The figures are for illustrative purposes, only, and are not intended to be to scale.

A first embodiment of the selective deposition method will be described along with FIGS. 1 to 6. An atomic layer deposition method serves to selectively deposit a layer of a first material in first areas of a structure, but to not deposit the material in second areas of the same structure. The method is essentially distinct to a method, according to which the material is deposited in both the first area and the second area and the material recently deposited in the second area is selectively removed afterwards.

An atomic layer deposition used in the embodiments is generally based on the use of two precursors. One of the precursors is a compound containing atoms to be deposited on a surface for forming the layer. This one of the two precursors chemically adsorbs on a surface basically only if the surface has been prepared previously, i.e. activated, with the other of the two precursors. The other of the two precursors may be an oxidizing reactant (oxidant), i.e. a reactant that gains electrons in a red-ox chemical reaction with the one precursor. The other precursor may or may not deposit atoms, usually oxygen O or nitrogen N, to the surface for contributing to the formation of the layer. If so, the other precursor basically only adsorbs to the surface at places the other precursor has not reacted with yet. A precise control of the thickness of the layer deposited is achieved by consecutively or alternatingly applying the two precursors to the surface.

In the context of the embodiments explained herein below, an atomic layer deposition refers to the use of a single precursor having a self limiting reaction. A surface is prepared such that the precursor adheres to or adsorbs on the surface. The precursor does not react with the precursor adsorbed on the surface, however. Thus, a precise control of the deposition of the precursor is obtained, i.e. a control on atomic or molecular level.

A detailed example of the first embodiment will be given along with FIGS. 1 to 6. The present invention is not limited to the details of this example. Alternatives for the structures illustrated, chemical reactions explained and chemicals used for the chemical reaction will be listed later on.

A silicon substrate 1 having a principal surface 2 is provided (FIG. 1). A trench 3 is formed through the principal surface 2 into the silicon substrate 1 as example for a structured surface. The trench 3 may have a high aspect ration of greater than 20:1. The trench 3 can be formed via an anisotropic etching technique. The lower part of the trench 3 forming the bottom 5 of the trench is denoted as bottle area 6 or bottle region and as example for a first area. The upper part of the trench 3 close to the principal surface is denoted as collar area 4 or collar region and is given as an example for a second area. The collar area 4 may have a smaller diameter than the bottle area 6 (not illustrated).

Water vapour 7 is applied to the trench 3 in order to grow silicon oxide 9 on side walls 8 of the trench 3. Typical temperatures for the growth of silicon oxide 9 by use of water may be for example in the range of 100° C. to 200° C. The growth rate of the silicon oxide 9 in the collar area 4 is greater than the growth rate in the bottle area 6 because of the stronger exposition of the collar area 4 to the water vapour 7. Thus, the silicon oxide 9 is thicker in the collar area 4 compared to the bottle area 6. The bottom 5 may be provided with or may be provided free of hydroxyl groups; FIG. 1 shows no hydroxyl groups in the bottom region just for sake of simplicity.

Along with the growth of the silicon oxide 9, hydroxyl functional groups (—OH) are formed on the surface of the silicon oxide 9, i.e. the side walls 8. Hence, the trench 3 is provided with hydroxyl functional groups in the collar area 4 and the bottle area 6 (FIG. 1).

The semiconductor substrate 1 is dipped into a solution of hydrofluoric acid 10 (HF). Silicon oxide is etched by the hydrofluoric acid. The hydroxyl groups are removed during the etching, as well. A bare silicon surface of the side walls 8 is passivated by the formation of hydrogen functional groups (—H). The duration of the dipping into the hydrofluoric acid solution is chosen such that the silicon oxide in the bottle area 6 is basically completely removed whereas silicon oxide still covers the side walls 8 in the collar area 4. Thus, the bottle area 6 exhibits a surface formed by silicon passivated by hydrogen functional groups (—H). The collar area 6, instead, is still provided with at least a thin silicon oxide layer 9 on which hydroxyl groups are present (FIG. 2). The hydroxyl groups (—OH) are constantly formed on the silicon oxide 9 via the watery hydrofluoric solution.

A first atomic layer deposition for depositing a passivation layer in the collar area 4 is performed.

A first precursor 11 of the first atomic layer deposition is chosen of alkyl chloro silanes. The constitutional formula of the alkyl chloro silane are at least one of CₙH₂ₙ₊₁—SiClH₂; CnH₂ₙ₊₁—SiCl₂H; and CₙH₂n+1-SiCl3. The number of carbon atoms n of the functional alkyl group is greater than four, or greater than eight or greater than ten. The reason for choosing long chained alkyl groups will be given in the next paragraphs.

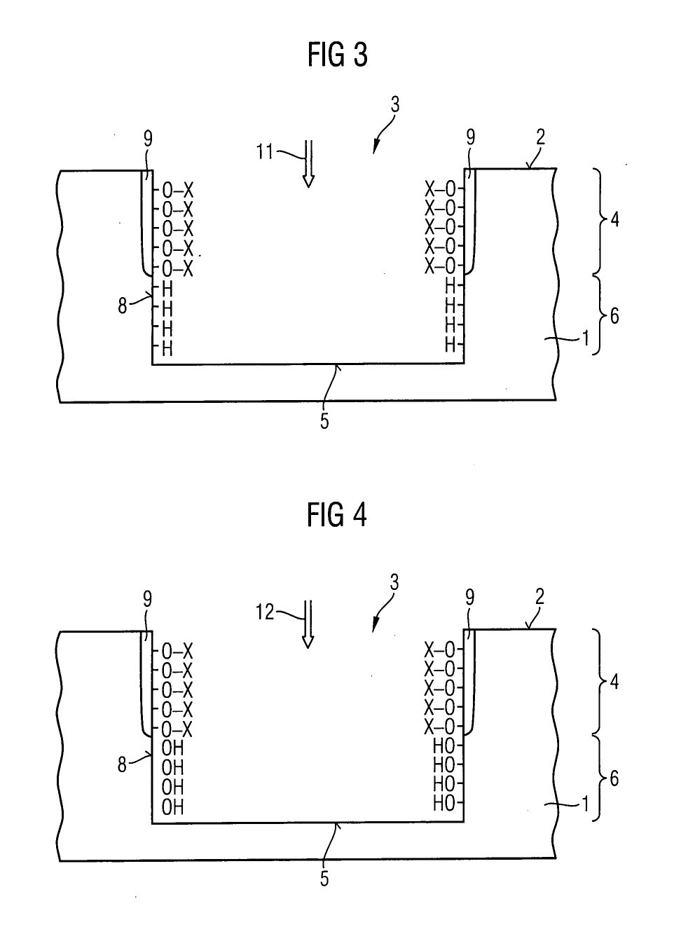

The first precursor 11 reacts with hydroxyl groups, but has a negligible reaction rate with hydrogen functional groups. Therefore, a chemical adsorption of the precursor 11 takes place in the collar area 4, but basically not in the bottle area 6. The chemically adsorbed first precursor 11 is denoted as —X in the FIG. 3. The chemical bond to the remaining oxygen of the hydroxyl group (as depicted) or to the silicon of the side wall is established by the silicon atom of the precursor 11. The long chained alkyl functional group of adsorbed first precursor X point away from the side walls 8 into the inner space of the trench.

The deposition or adsorption of the first precursor 11 on the side wall 8 in the collar area 4 is self limited. Thus, a single monolayer of the adsorbed first precursor X is deposited. The thickness of the monolayer deposited approximately equals to the length of the alkyl group. The diameter of the trench 3 in the collar area 4 may be reduced by about 1 to 2 nm.

The alkyl groups are forming a passivation layer for the underlying side wall 8. The alkyl groups do not react with weak reactants, e.g. water. Further, the reaction of the first precursor removes the reaction sites for the following deposition process.

Alkyl groups of a length of up to twenty carbon atoms can be deposited by gas phase deposition techniques, e.g. atomic layer deposition, chemical vapour deposition.

The first precursor 11 may be introduced into a reaction chamber along with an inert purge gas, like argon, nitrogen, etc. The partial pressure of the first precursor 11 can be for example in the range of 13-1300 Pa (0.1-10 Torr) in the reaction chamber. The temperature is in the range of 70° C. to 200° C., for instance.

The further steps are depositing a layer of a desired material, e.g. hafnium oxide or zirconium oxide, selectively in the bottle area 6 of the trench 3.

An oxidant 12 is introduced into the reaction chamber. The oxidant can be water, for instance. The oxidant transforms the hydrogen functional groups in the bottle area 6 to hydroxyl functional groups. The processing conditions may be similar to the growth of the silicon oxide 9 taught herein above. The application duration of the oxidant 12 is very brief in order to avoid the formation of a thick silicon oxide layer in the bottle area 6, but sufficiently long to form hydroxyl groups on the side walls 8 in the bottle area 6 (FIG. 4). Process conditions may be met to form a silicon oxide of about 1 nm or less.

The long chained alkyl groups of the adsorbed first precursor X inhibit the transport of water 12 and other oxidants to the surface of the side walls 8. Thus water cannot break up the chemical bonding of the alkyl groups to their corresponding silicon atom. Further, water is chosen because it basically does not react with the alkyl groups. In particular, water does not replace one of the hydrogen atoms of the alkyl by a hydroxyl group.

Long chained alkyl groups are hydrophobic. They can inhibit a reaction with polar reactants, e.g. water.

The bottle area 6 is selectively prepared for a second atomic layer deposition technique based on a precursor selectively reacting with hydroxyl groups. The collar area 6 is passivated by the alkyl groups and thus the second atomic layer deposition technique will not deposit material in the collar area 4. Exemplarily, the deposition of hafnium oxide in the bottle area 6 will be described.

The second atomic layer deposition technique employs a second precursor 13 chosen among compounds of the constitutional formula MR¹R²R³R⁴. M designates hafnium; other transition metals like zirconium can be used as well. At least one of R¹, R², R³, and R⁴ is independently selected of alkyl amine functional groups. Alkyl amine functional groups are of the constitutional formula (—NR⁵R⁶); R⁵, R⁶ are independently selected of alkyl functional groups. The remaining of R¹, R², R³, and R⁴ are selected of hydrogen and alkyl functional groups (CₙH₂ₙ₊₁). An other example of a precursor 13 employed has the constitutional formula M (R¹CP)₂ (R²R³). M can be selected as above. Cp is cyclopentadienyl, R¹ is independently selected of hydrogen and alkyl, methyl or ethyl, and R², R³ are independently selected of hydrogen, alkyl-methyl and ethyl- and alkoxy (—O—CₙH₂ₙ₊₁).

The second precursor 13 reacts with the hydroxyl groups and forms an adsorbed second precursor denoted R in FIG. 5. The hafnium atom is bound with an oxygen atom to silicon of the side wall. The organic part of the second precursor point into the trench 3.

The temperature for the deposition in the reaction chamber depends on the precursor 13 used. For instance, a temperature range of 150° C.-350° C. is used for precursors 13 based on alkyl amid compounds. A higher temperature range up to 500° C. may be used for precursors 13 based on cyclopentadienyl. The second precursor 13 may be introduced into a reaction chamber along with an inert purge gas, like argon, nitrogen, etc. The partial pressure of the second precursor 11 can be for example in the range of 13-1300 Pa (0.1-10 Torr).

A second oxidant 14 is introduced into the reaction chamber. The oxidant 14 may be identical to the first oxidant 12, e.g. water, used to form the hydroxyl groups in the bottle area 6. The second oxidant 14 serves as the counter part (other precursor) to the second precursor 13 used for the second atomic layer deposition method. An alternating application of the second oxidant 14 and the second precursor 13 deposits a layer of hafnium oxide on the side wall 8 in the bottle area 6. The organic parts of the adsorbed second precursor R are transformed by water into volatile or soluble compounds. A hydroxyl group is formed on the hafnium bound to the side wall 8.

Despite the second oxidant 14 reacts with the adsorbed second precursor R in the bottle area 6, the second oxidant 14 is chosen to not react with the alkyl groups of the adsorbed first precursor X in the collar area 4.

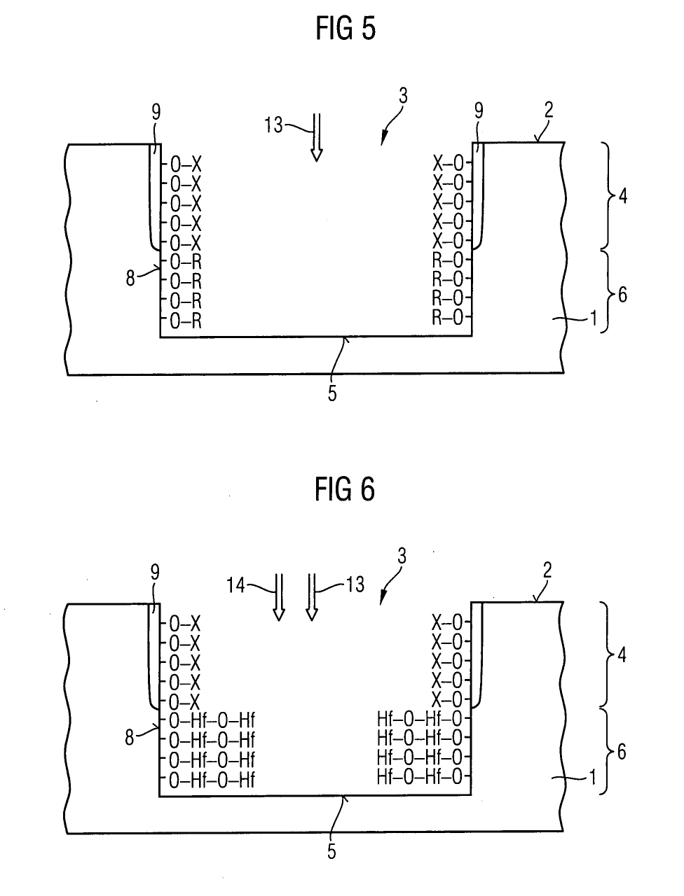

The precursor 13 and the oxidant 14 may be applied alternatingly several times. FIG. 6 illustrates the outcome for hafnium (Hf) as metal M. A layer of hafnium oxide is formed in the bottle area 6 of the trench 3. The collar area 4 is basically free of the hafnium oxide.

Steps not illustrated include the removal of the alkyl groups in the collar area 4, e.g., by a strong oxidizing agent. A selective etch process, e.g., ozone, plasma oxidation, is employed which etches the alkyl groups and does not affect the deposited layer in the bottle area 6. An electrode is deposited in the bottle area 6 for completing the formation of a capacitor.

The above first embodiment deposits a hafnium oxide layer in the bottle region 6 by alternatingly employing the second precursor 13 and water as the second oxidant 14. Water oxidizes the second precursor 14, more precisely the chemically absorbed second precursor R, and does not interact with the alkyl groups of the chemisorbed first precursor X.

A further embodiment makes use of alkyl chloro alanes (alkyl chloro aluminium hydrid) as first precursor 11 having one of the constitutional formulas R¹AlClH and R¹AlCl₂. R¹ denotes an alkyl functional group. Alkyl carbooxylates having the constitutional formula R²— COOH and alkyl sulfates having the constitutional formula R³SO₄ serve as first precursor 11 in other embodiments. In further embodiments the first precursor 11 has the formula R⁴CₙFₓH₂ₙ₊₁₋ₓ, wherein CₙFₓH₂ₙ₊₁₋ₓ is a fluorinated alkyl, i.e. at least one of the hydrogen atoms of the alkyl is substituted by fluorine. The amount x of hydrogen atoms substituted by fluorine can be up to 2n+1, n denoting the number of carbon atoms. Each of the alkyl group R¹, R², R³, and R⁴ are long chained having up to twenty, eight to fifteen, or ten to twelve carbon atoms. The chemisorbed first precursor 11 is chemically bonded to the side wall 8 such that the long chained alkyl group points away from the side wall 8. Hence, the underlying working principle of these first precursors 11 is similar to the above alkyl chloro silane.

The chemisorbed first precursor 11 is chemically bound to the side wall 8 such that the long chained alkyl group points away from the side wall 8. Hence, the underlying working principle of these first precursors 11 is similar to the above example using alkyl chloro silane.

The first oxidant 12 and the second oxidant 14 can be chosen among water, diatomic oxygen and ozone (O₃) in case of the above listed first precursors 11. The alkyl groups of the first precursor are sufficiently chemical stable against such first and second oxidants 12, 14 and do not substitute hydrogen to hydroxyl groups at the alkyl groups.

The above embodiments referred to the formation of hafnium oxide in the bottle area 6 of the trench 3. A deposition of hafnium nitride can be performed by using at least one of ammonia NH₃ and hydrazine N₂H₄ as oxidant. An oxidizing reactant or oxidant is defined to be a reactant that gains electrons in a redox chemical reaction with the one precursor. Thus, the terms oxidizing reactant and oxidant are not limited to a reactant donating an oxygen atom to its reaction partner.

Ammonia and hydrazine do not form hydroxyl, groups but amine functional groups (—NH₂) on the surface of silicon nitride or silicon oxide. The first precursors 11 and second precursors 13 listed herein above do react with amine functional groups like they do with hydroxyl groups, at least in concerns of the described selective deposition method. The alkyl groups of the first precursor 11 are sufficiently inactive with regard to the ammonia and hydrazine such that no hydrogen of the alkyl is substituted by an amine group. Thus, the adsorbed first precursor X forms a passivation layer. The second precursor 13 finds reaction places in the bottle area 6, but basically not in the collar area 4. An alternating application of the second precursor 13 and of ammonia or hydrazine deposits hafnium nitride, for instance, basically only in the bottle area 6.

The selective formation of a zirconium oxide and zirconium nitride can be in the bottle area 6 can be achieved by using the second precursor wherein M is zirconium.

Hafnium oxide and zirconium oxide can be doped with silicon. Along with the second precursor 13 or sequentially to the second precursor 13, a precursor transporting silicon can be introduced into the reaction chamber. The ratio of silicon to hafnium (zirconium) may be in the range of 1 to 20 atomic percent. This ratio is controlled by the amount of injections of the second precursor 13 and the amount of injections of the silicon providing precursor. The precursor for silicon may be trisdimethylaminosilane, for instance.

The deposition of aluminium oxide or aluminium nitride in the bottle area 6 is achieved by choosing the second precusor of trimethylaluminium (TMA), tris dimethyl amino silane (TDMAS) and trisdimethyl amino silane (3DMAS), tetrakis dimethyl amino silane (4DMAS) and N,N,N′,N′-tetraethyl silan diamine.

The second atomic layer deposition can be used to deposit selectively purely metallic layers in the bottle area 6. The second precursor 13 can be chosen of one of Ru(Ethyl Cp)₂, Iridium(acethyl acetat)₃, TiCl₄ and/or WF₆ to deposit ruthenium, iridium, titanium nitride and/or tungsten. The second oxidant 14 is chosen of one of the above listed oxidants water, oxygen, ozone, ammonia, and hydrazine.

A selective deposition of silicon oxide or silicon nitride can be achieved by using tris dimethyl amino silane as second precursor 13, for instance.

Instead of using a first atomic layer deposition technique the passivation layer can be selectively formed in the collar region by a gas phase deposition technique, a spin-on technique, and a dip-in technique using a watery solution of a reactant. The reactant is chosen like the first precursors of one of the above compounds. The reactant will react with the activated collar region, but basically not with the bottle region. Thus, the passivation layer is generated. The reactant forms only a thin layer, preferably a monolayer, hence, a closing of the collar region will not occur.

A second embodiment of a selective deposition method is explained along with FIGS. 7 to 9. The second embodiment differs to the first embodiment just in the starting sequence. Hence, the deposition method can be continued as explained along with the FIGS. 2 to 6, as it will become obvious and outlined later on.

A trench 3 is formed in a semiconductor substrate 1. Hydroxyl groups and/or amine groups (not displayed) are saturating the side walls 8 of the trench 3 (see FIG. 1). The hydroxyl groups may be generated by applying water to the trench 3.

An aluminium oxide layer 20 is deposited in the trench 3 by a third atomic layer deposition technique. The one precursor 21 can be chosen among trimethylaluminium (TMA), and trisdimethyl amino silane (3DMAS), tetrakis dimethyl amino silane (4DMAS) and N,N,N′,N′-tetraethyl silan diamine; the other precursor 22 be chosen among water, ozone, and diatomic oxygen.

The one precursor 21 of the third atomic layer deposition has a very high affinity to hydroxyl groups. Thus, the one precursor 21 usually adsorbs at the first attempts and contacts to the side wall 8. The one precursor 21 basically first covers the collar area 4 before the one precursor 21 passed deeper into the trench 3. The second embodiment limits the amount of the injected one precursor 21 to the amount necessary to cover the collar area 4. Thus, the bottle area 6 remains basically free of the one precursor 21. Test runs are necessary to determine the amount of the one precursor 21. Parameters to be controlled are the time of injection of the one precursor 21 into a reaction chamber and the pressure in the reaction chamber. Exemplary parameters can be in the range of 0.1 to 0.2 seconds at a partial pressure of the one precursor in the range of 13-1300 Pa (0.1-10 Torr). It is understood that these parameters heavily depend on the dimensions of the side walls and structures to be covered with aluminium oxide (Al₂O₃). The other precursor 22 transforms the adsorbed one precursor 21 to aluminium oxide having hydroxyl groups at its surface (FIG. 8).

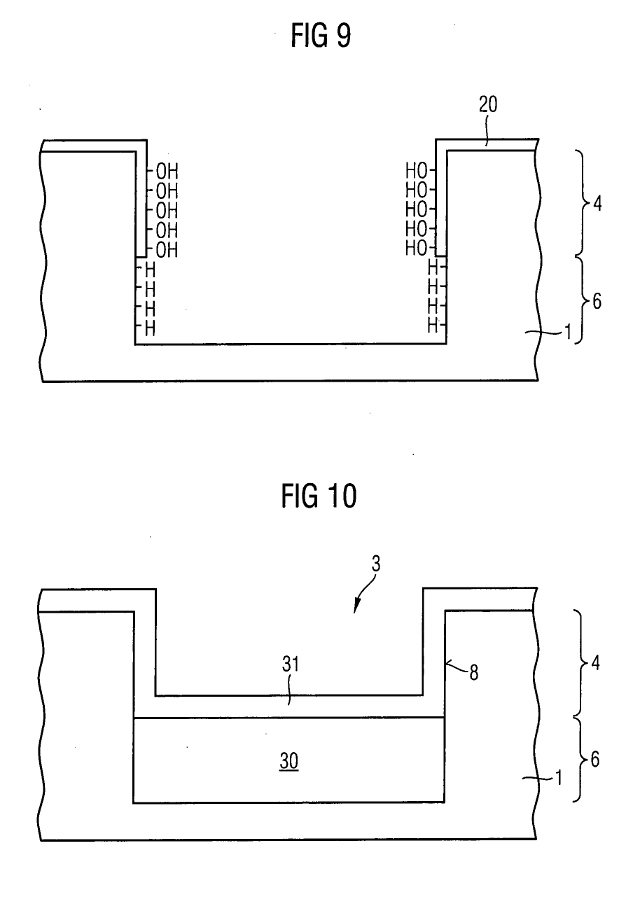

The aluminium oxide layer is thus basically only created in the collar area 4. The substrate 1 is dipped into hydrofluoric acid to etch silicon oxide in the bottle area 6. The side wall 8 in the bottle area 6 is cleared of hydroxyl groups (FIG. 9). The aluminium oxide layer 20 is chemically stable versus the hydrofluoric acid. Thus, hydroxyl groups remain provided in the collar area 4. This situation corresponds to the one discussed along with FIG. 3. The first atomic layer deposition can be performed and will just deposit a passivation layer in the collar area 4. Afterwards, the second atomic layer deposition is performed to deposit the desired layer selectively in the bottle area 6 of the trench 3. A detailed description of the first and second atomic layer deposition is omitted; reference is made to the first embodiment and its examples.

Aluminium nitride can be deposited in the collar area 4 instead of the formation of aluminium oxide without change to the above second embodiment. The other precursor can be chosen from ammonia and hydrazine.

A thick silicon oxide layer can be grown in the collar area 4 by the third atomic deposition, too. Trisdimethylaminosilane can be used as one precursor 21. The thick silicon oxide layer will be etched by the hydrofluoric acid. The parasitic silicon oxide in the bottle area 6 will be removed completely before the thicker silicon oxide in the collar area is etched away. Thus, the duration of the application of the hydrofluoric acid is chosen such that basically only the parasitic silicon oxide along with its hydroxyl groups is removed and the silicon oxide in the collar area 4 along with its hydroxyl groups still covers the side walls 8.

A third embodiment is illustrated along with FIGS. 10 to 12. The third embodiment differs to the first embodiment just in the starting sequence. Hence, the deposition method can be continued as explained along with the FIGS. 2 to 6, as will become obvious and outlined later on.

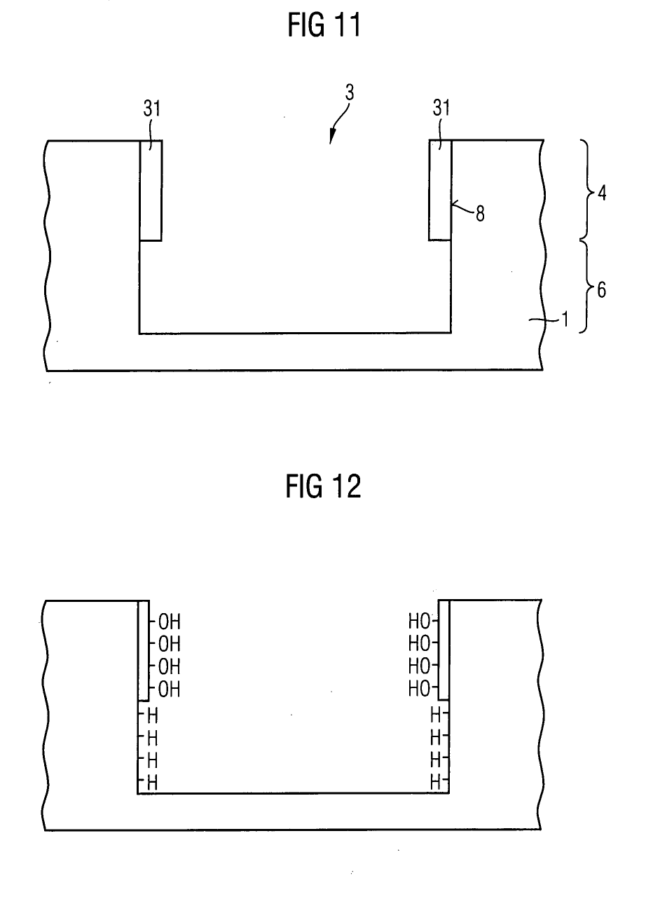

A trench 3 is formed in a semiconductor substrate 1 (FIG. 10). The trench 3 is filled with a sacrifice material 30 in the bottle area 6 of the trench 3. The collar area 4 remains unfilled. The sacrifice material can be silicon nitride, spin-on-glass, for instance. The sacrifice material can be spinned on, deposited in gas phase, etc. A layer 31 of silicon oxide 31 is deposited on the side walls 8 in the collar area 4. An aniostropic etch removes the masking layer 31 except from the side walls 8. The sacrifice material 30 can be selectively etched such that the silicon oxide layer 31 remains on the side walls 8 in the collar area 4, as depicted in FIG. 11.

The thick silicon oxide layer will be partially etched by the hydrofluoric acid. The parasitic silicon oxide in the bottle area 6 will be removed completely before the thicker silicon oxide in the collar area is etched away. The duration of the application of the hydrofluoric acid is chosen such that basically only the parasitic silicon oxide along with its hydroxyl groups is removed and the silicon oxide in the collar area 4 along with its hydroxyl groups still covers the side walls 8 (FIG. 12). This situation corresponds to the one discussed along with FIG. 3. The first atomic layer deposition can be performed and will just deposit a passivation layer in the collar area 4. Afterwards, the second atomic layer deposition is performed to deposit the desired layer selectively in the bottle area 6 of the trench 3. A detailed description of the first and second atomic layer deposition is omitted; reference is made to the first embodiment and its examples.

A forth embodiment is illustrated along with FIGS. 13 to 15. A substrate 1 is provided with a contact area 40. The contact area is metallic or of any other conducting material. A dielectric layer 41, e.g. an inter dielectric layer (IDL) is deposited on the substrate 1. A trench 42 is formed into the dielectric layer 41 for laying free the contact area 40 (FIG. 13).

The consecutive steps fill the trench 42 with a conductive material to form a via. The via is an example for a vertical conductive interconnect. Alike one of the above illustrated embodiments an upper area 4 of the trench 42 is passivated by a passivation layer. The lower area 6 of the trench 42 is activated. Its surface is provided with hydroxyl- or amin-functional groups.

The lower part of the trench 42 is filled with a conductive material 44 using an atomic layer deposition technique (FIG. 14). The pre-cursors used by the atomic layer deposition technique are chosen to not react with the passivation layer OX. Examples for such pre-cursors are given in the above embodiments. A closing of the trench 42 in the upper area 4 before the lower part 6 of the trench 42 is filled may be inhibited by this approach of a filling method.

The passivation layer is removed. The remaining upper part of the trench can be filled by the same atomic layer deposition technique or any other deposition technique (FIG. 14).

Although the present invention has been described with reference to embodiments, it is not limited thereto, but can be modified in various manners which are obvious for persons skilled in the art. Thus, it is intended that the present invention is only limited by the scope of the claims attached herewith.

The above embodiments refer to the formation of a capacitor, in particular to the deposition of dielectric layer in a trench. The selective deposition technique can be applied for the manufacturing of electrodes and electric interconnections made of metals or conductive compounds, too.

The selective deposition may applied to a filling of trenches. The filling can be selectively started in the bottom area by passivating the upper area as taught with the above embodiments. After the filling of the bottom area, the trench can be filled completely or again just a lower part is filled. Such a filling may be favourable for filling of trenches having large aspect ratios in order to avoid voids in the filling.

Multiple structures are exhibiting vertical surfaces or surfaces inclined to a principle surface of a substrate. A deposition of material on the lower part of such surfaces, i.e. closer to the substrate, selectively to the upper part can be achieved by the above embodiments. Other structures are exhibiting surfaces being essentially parallel but in different layers. A selective deposition on the lower layer or upper layer can be performed according to one of the above embodiments.

Along to the deposition of the hafnium oxide or zirconium oxide a dopant can be applied. The dopant can be chosen of at least one of silicon, aluminium, rare earth metal, titanium, hafnium, tantalum, barium, scandium, yttrium, lanthanum, niobium, bismuth, calcium and cerium.

What is claimed is:

1. A selective deposition method comprising the following steps of:
(a) providing a substrate comprising at least one structured surface, the structured surface comprising a first area and a second area;
(b) selectively passivating the first area regarding reactants of a first deposition technique and activating the second area regarding the reactants of the first deposition technique;
(c) depositing a passivation layer on the second area via the first deposition technique, the passivation layer being inert regarding a precursor selected from a group of oxidizing reactants;
(d) depositing a layer in the second area using a second atomic layer deposition technique as a second deposition technique using the precursor selected form the group of oxidizing reactants.

2. The selective deposition method according to claim 1, wherein first deposition technique is a first atomic layer deposition technique and the reactants being precursors of the first atomic layer deposition technique.

3. The selective deposition method according to claim 1, wherein the first deposition technique is one of a gas phase deposition technique providing the reactant, a spin-on technique providing the reactant, and a dip-in technique using a watery solution of the reactant.

4. The selective deposition method according to claim 1,
wherein the first area is passivated by removing at least one of hydroxyl functional groups and amine functional groups from the first area and
wherein the second area is activated by forming the at least one of hydroxyl functional groups and amine functional groups on the second area, which are removed in the first area.

5. The selective deposition method according to claim 1,
wherein the selective passivating of the first area and the selective activating of the second area comprises the steps of:
(a) selectively forming a layer of at least one of a silicon oxide layer and a silicon nitride layer on the second area;
(b) selecting an etchant of a group of etchants etching silicon oxide when the layer is formed to comprise silicon oxide and is chosen of a group of etchants etching silicon nitride when the layer is formed to comprise silicon nitride;
(c) applying the etchant to the first area and to the second area for a duration such that parasitic silicon oxide and parasitic silicon nitride are removed in the first area and the formed silicon oxide and the formed silicon nitride remains in the second area.

6. The selective deposition method according to claim 5, wherein the first area is masked for selectively forming the layer of at least one of a silicon oxide layer and a silicon nitride layer on the second area.

7. The selective deposition method according to claim 1,
wherein the selective passivating of the first area and the selective activating of the second area comprises the steps of:
(a) selectively forming a layer of a silicon oxide layer on the second area; and
(b) etching the first area and the second area until parasitic silicon hydroxyl is removed in the first area using an etchant being selected of hydrofluoric acid or a mixture comprising hydrofluoric acid and ammonia.

8. The selective deposition method according to claim 2,
wherein the selective passivating of the first area and the selective activating of the second area comprises the steps of:
(a) selectively forming a layer of at least one of a aluminium oxide and a aluminium nitride on the second area via a non-conformal atomic layer deposition technique; and
(b) applying an etchant to the first area and the second area until parasitic silicon hydroxyl is removed in the first area, the etchant being selected of a species the layer is inert against.

9. The selective deposition method according to claim 8, wherein the etchant is chosen of hydrofluoric acid or a mixture comprising hydrofluoric acid and ammonia.

10. The selective deposition method according to claim 1, wherein the group of oxidizing reactants is selected of at least one of water, ozone, diatomic oxygen, ammonia and hydrazine.

11. The selective deposition method according to claim 1,
wherein the first atomic layer deposition technique employs a precursor chosen from a group of compounds of the constitutional formulas R¹Si Cl₃, R²AlCl₂, R³COR⁴, R⁵SO₂R⁶, and R⁷CₙFₓH₂ₙ₊₁₋ₓ, wherein R¹, R², R³, R⁴, R⁵, R⁶, and R⁷ are independently selected of alkyl functional groups.

12. The selective deposition method according to claim 11, wherein R¹, R², R⁴, and R⁵ are alkyl functional groups comprising four to twenty carbon atoms.

13. The selective deposition method according to claim 1,
wherein the first atomic layer deposition technique employs a precursor chosen from a group of hexamethyldisilizane (HN[Si(CH₃)₃]₂), decyltrichlorsilane (SiCl₃C₁₀H₂₁) and, octadecyltrichlorsilane (SiCl₃C₁₈H₃₇).

14. The selective deposition method according to claim 1, wherein the substrate comprises a trench, the at least one structured surface is provided as a side wall of a trench and the first area is closer to a bottom of the trench than the second area.

15. The selective deposition method according to claim 1, wherein the substrate comprises a bottom surface and at least one structure surface having a first area and a second area, the first area being closer to the bottom surface than the second area.

16. A selective deposition method comprising the following steps of:
(a) providing a silicon substrate comprising a bottom surface and at least one structured surface, the structured surface comprising a first area and a second area, the first area being closer to the bottom surface than the second area;
(b) selectively depositing at least one of silicon oxide and aluminium oxide on the second area;
(c) etching the first area and the second area until parasitic silicon hydroxyl is removed in the first area;
(d) depositing a passivation layer on the second area being inert against at least one of water and ozone via a first atomic layer deposition technique, the first atomic layer deposition technique using at least one of hexamethyldisilizane (HN[Si(CH₃)₃]₂), decyltrichlorsilane (SiCl₃C₁₀H₂₁), and octadecyltrichlorsilane (SiCl₃C₁₈H₃₇) as precursor;
(e) activating the passivated first area using at least one of water and ozone for forming silicon hydroxyl in the second area;
(f) depositing a transition metal oxide via a second atomic layer deposition technique using one precursor selected from water and ozone and an other precursor chosen as compound of one of the constitutional formulas M(R¹Cp)₂ (R²)₂ and MR³R⁴R⁵R⁶, wherein M is one of hafnium and zirconium, Cp is cyclopentadienyl, R¹ is independently selected of hydrogen, and alkyl, R² is independently selected of hydrogen, methyl, ethyl, alkyl, alkoxy, and halogene; and R³, R⁴, R⁵, and R⁶ are independently selected of hydrogen and alkyl amines.

17. A structured semiconductor device, comprising:
a substrate comprising at least one structured surface, the structured surface comprising a first area and a second area, and
a layer comprising at least one of a transition metal oxide and a transition metal nitride on the second area deposited via an atomic layer deposition technique, the second area being substantially free of the at least one of the transition metal oxide and the transition metal nitride.

18. An integrated electronic circuit, comprising:
a structured semiconductor substrate in which a trench is formed, the trench comprising a collar region, and a bottle region;
a dielectric layer of at least one of a transition metal oxide and a transition metal nitride formed on the second surface deposited via an atomic layer deposition technique, the bottle region being substantially free of the at least one of the transition metal oxide and the transition metal nitride.

19. A memory device comprising the integrated electronic circuit according to claim 18.

20. The selective deposition method according to claim 6, the structured surface being a trench in the substrate, the first area being a bottom area of the trench, wherein the first area is masked by filling the bottom area of the trench.

21. The selective deposition method according to claim 16, wherein a dopant is applied along to depositing the transition metal oxide, the dopant being chosen of at least one of silicon, aluminium, rare earth metal, titanium, hafnium, tantalum, barium, scandium, yttrium, lanthanum, niobium, bismuth, calcium and cerium.
